(19) United States
(12) Patent Application Publication
(10) Pub. No.: US 2023/0085583 A1
(43) Pub. Date: Mar. 16, 2023

(54) THREE DIMENSION MEMORY DEVICE

(71) Applicant: MACRONIX International Co., Ltd., Hsinchu (TW)

(72) Inventors: Yung-Feng Lin, Taoyuan City (TW); Su-Chueh Lo, Hsinchu City (TW); Teng-Hao Yeh, Hsinchu County (TW); Hang-Ting Lue, Hsinchu (TW)

(73) Assignee: MACRONIX International Co., Ltd., Hsinchu (TW)

(21) Appl. No.: 17/477,229

(22) Filed: Sep. 16, 2021

(51) Int. Cl. G11C 16/24; G11C 16/10; G11C 16/16; G11C 16/26; H01L 27/11556; H01L 27/11526; H01L 27/11582; H01L 27/11573

(52) U.S. Cl. CPC G11C 16/24; G11C 16/10; G11C 16/16; G11C 16/26; H01L 27/11556; H01L 27/11526; H01L 27/11582; H01L 27/11573

(57) ABSTRACT

A three dimension memory device, such as a three dimensional AND flash memory is provided. The three dimension memory device includes a plurality of memory arrays, a plurality of bit line switches, and a plurality of source line switches. The memory array has a plurality of memory cell rows respectively coupled to a plurality of source lines and bit lines. The bit line switches and the source line switches are respectively implemented by a plurality of first transistors and second transistors. The first transistors are coupled to a common bit line and the bit line. The second transistors are coupled to a common source line and the source lines. The first transistors are P-type transistors or an N-type transistors with a triple-well substrate, and the second transistors are P-type transistor or an N-type transistors with a triple-well substrate.

### BACKGROUND

### Technology Field

The disclosure relates to a three dimension memory device, and more particularly to a three dimension memory device capable of providing negative source line voltages or bit line voltages.

### Description of Related Art

With the advancement of semiconductor process technology and the improvement of electronic product functions, it has become a trend to install highly dense flash memory on electronic products.

In conventional three dimension AND flash memory, bit line switches and source line switches are often constructed through N-type transistors. In this case, the bit line switch and the source line switch may only provide the memory cell with positive word line voltages and source line voltages so that the memory cell perform programming or erase operations. However, the memory cell is in the programming or erase operation, so the memory cell may be a selected memory cell or an unselected memory cell. To enable the selected memory cell to effectively perform programming or erase operations and to enable the unselected memory cell to be masked without being disturbed, how to provide each memory cell with an appropriate bias voltage under the restriction of the process conditions has become a difficult subject.

### SUMMARY

The disclosure provides a three dimension memory device capable of providing appropriate bit line voltages and source line voltages to each memory cell.

The three dimension memory device of the disclosure includes multiple memory arrays, multiple bit line switches, and multiple source line switches. The memory array has multiple corresponding memory cell rows, and the memory cell rows are respectively coupled to multiple source lines and multiple bit lines. The bit line switches are respectively configured with multiple first transistors. First ends of the first transistors are coupled to a common bit line, and second ends of the first transistors are respectively coupled to the bit lines. The source line switches are respectively configured with multiple second transistors. Second ends of the second transistors are coupled to the common source line, and second ends of the second transistor are respectively coupled to the source lines. The first transistors are P-type transistors or N-type transistors with a triple-well substrate, and the second transistors are P-type transistors or N-type transistors with a triple-well substrate.

In summary, in the three dimension memory device of the disclosure, a source line switch and a bit line switch are configured through a P-type transistor or an N-type transistor with a triple-well substrate. In the three dimension memory device of the disclosure, the source or drain may pass a positive or negative voltage by controlling the voltage on the well region of the P-type transistor and/or the N-type transistor. In this way, the source line switch and the bit line switch may provide appropriate voltages to the selected and unselected memory cells, so that each memory cell may complete the reading, programming, and erase operations.

### BRIEF DESCRIPTION OF THE DRAWINGS

FIG. 1 is a schematic view of a three dimension memory device according to an embodiment of the disclosure.

FIG. 2 is a schematic view of an implementation of an N-type transistor with a triple-well substrate in a three dimension memory device according to an embodiment of the disclosure.

FIG. 3A to FIG. 3D are schematic views illustrating access operations of a three dimension memory device according to an embodiment of the disclosure.

FIG. 4A to FIG. 4D are schematic views illustrating access operations of a three dimension memory device according to another embodiment of the disclosure.

FIG. 5A to FIG. 5D are schematic views of access operations of a three dimension memory device according to another embodiment of the disclosure.

FIG. 6A to FIG. 6D are schematic views of access operations of a three dimension memory device according to another embodiment of the disclosure.

### DESCRIPTION OF THE EMBODIMENTS

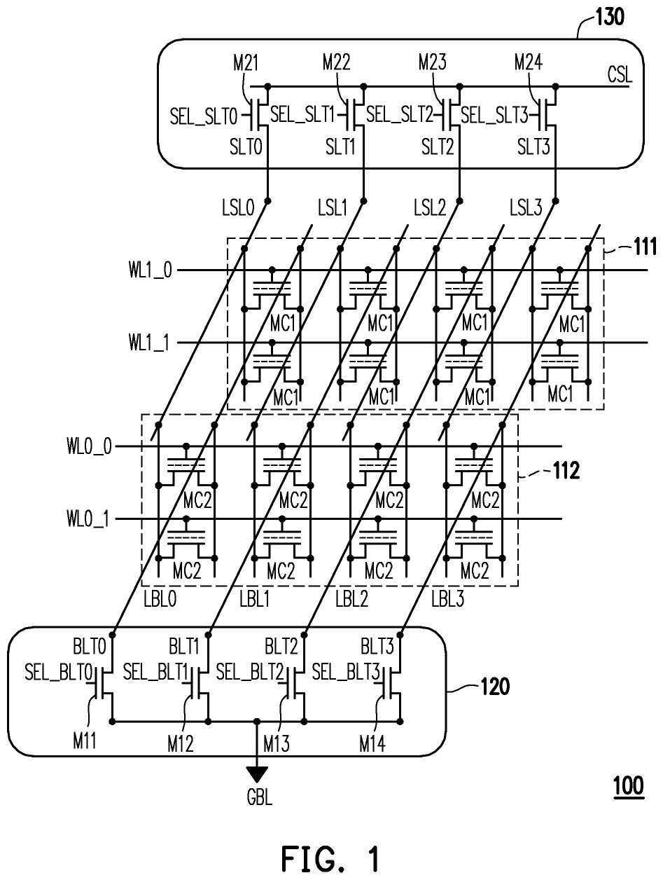

Referring to FIG. 1, FIG. 1 is a schematic view of a three dimension memory device according to an embodiment of the disclosure. A three dimension memory device 100 includes memory arrays 111 and 112, bit line switches BLT0 to BLT3, and source line switches SLT0 to SLT3. The memory array 111 includes multiple memory cells MC1. The memory array 112 includes multiple memory cells MC2. In the memory array 111, the memory cell MC1 is arranged into multiple memory cell rows and memory cell columns. In the memory array 112, the memory cells MC2 are also arranged into multiple memory cell rows and memory cell columns. The memory cell columns in the memory array 111 are respectively coupled to the word lines WL1_0 to WL1_1, and the memory cell columns in the memory array 112 are respectively coupled to the word lines WL0_0 to WL0_1. Moreover, the memory cell rows of the memory arrays 111 and 112 correspond to each other and are respectively coupled to the bit lines LBL0 to LBL3 and the source lines LSL0 to LSL3.

The bit line switches BLT0 to BLT3 are disposed in a substrate 120. The bit line switches BLT0 to BLT3 are respectively configured with multiple transistors M11 to M14. The source line switches SLT0 to SLT3 are disposed in a substrate 130. The source line switches SLT0 to SLT3 are respectively configured with multiple transistors M21 to M24. The transistors M11 to M14 are respectively controlled to be turned on or cut-off by selection signals SEL_BLT0 to SEL_BLT3. The transistors M21 to M24 are respectively controlled to be turned on or cut-off by selection signals SEL_SLT0 to SEL_SLT3.

In the embodiment, the transistors M11 to M14 may be P-type transistors or may also be N-type transistors with a triple-well substrate. The transistors M21 to M24 may be P-type transistors or may also be N-type transistors with a triple-well substrate.

Furthermore, the memory arrays 111 and 112 in the embodiment are AND type flash memory arrays. Moreover, in the embodiment of the disclosure, a single source line is coupled to a common source line CSL only through a corresponding single source line switch. A single bit line is coupled to a common bit line GBL only through a corresponding single bit line switch.

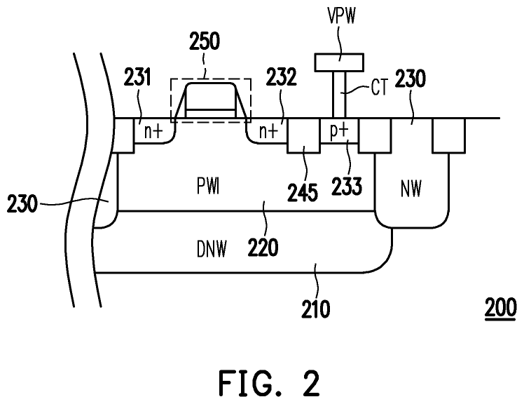

Referring to FIG. 2, FIG. 2 is a schematic view of an implementation of an N-type transistor with a triple-well substrate in a three dimension memory device according to an embodiment of the disclosure. An N-type transistor 200 includes an N-type deep well region (DNW) 210, a P-type well region (PWI) 220, an N-type well region 230, N-type heavily doped regions (n+) 231 and 232, a P-type heavily doped region (p+) 233, and a gate structure 250. The N-type deep well region (DNW) 210 may be formed in a P-type substrate. The P-type well region (PWI) 220 is formed on the N-type deep well region (DNW) 210 and is surrounded by the N-type well region 230. The N-type heavily doped regions (n+) 231 and 232 and the P-type heavily doped region (p+) 233 are sequentially disposed on the P-type well region (PWI) 220. The N-type heavily doped regions (n+) 232 and the P-type heavily doped region (p+) 233 may be isolated by an insulating structure 245. The N-type heavily doped regions (n+) 231 and 232 may be used to form a channel, and the gate structure 250 covers the upper part of the channel and covers part of the N-type heavily doped regions (n+) 231 and 232.

In the embodiment, a bias voltage VPW may be transmitted to the P-type heavily doped region (p+) 233 through a connection structure CT and is applied to the P-type well region (PWI) 220. By controlling the bias voltage VPW and the voltage on the N-type deep well region (DNW) 210, the N-type heavily doped regions (n+) 231 and 232 used as the source and drain (or drain and source) of the transistor 200 may be used to transmit a negative or positive voltage.

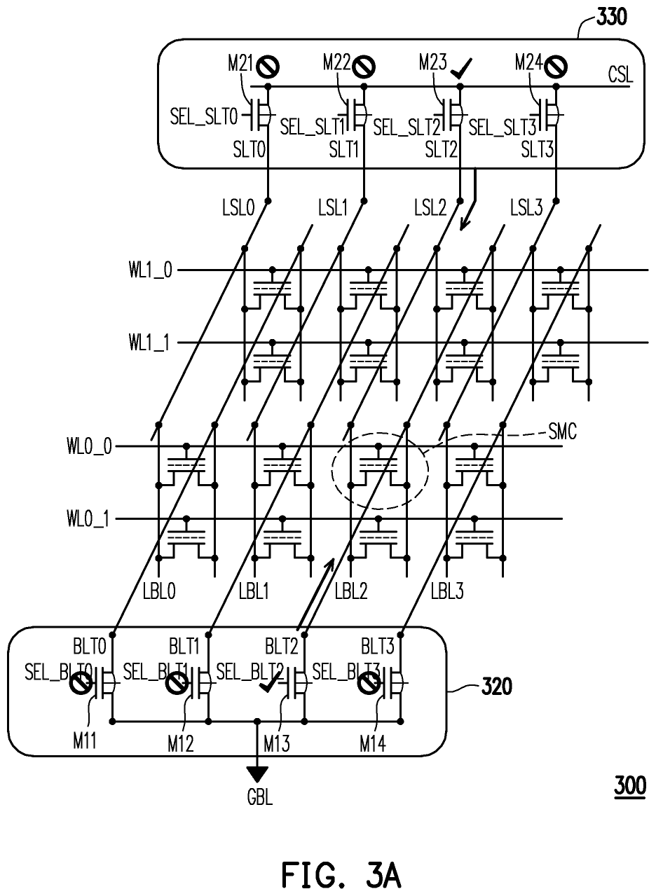

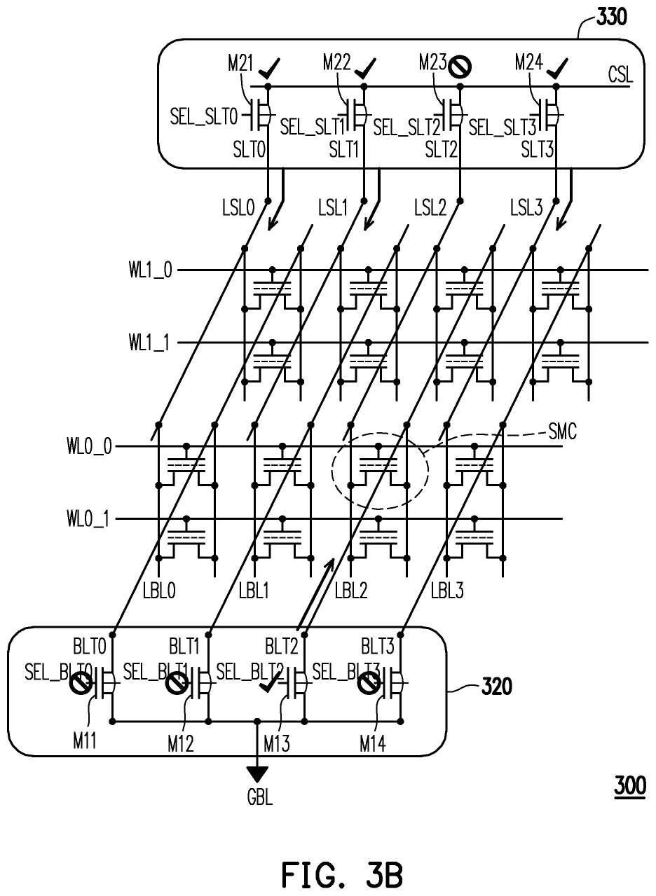

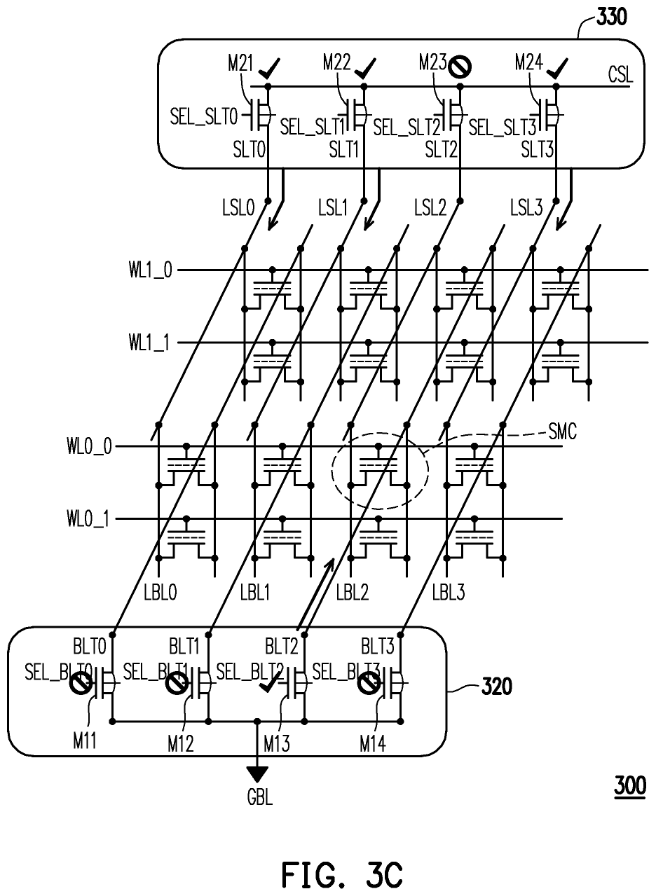

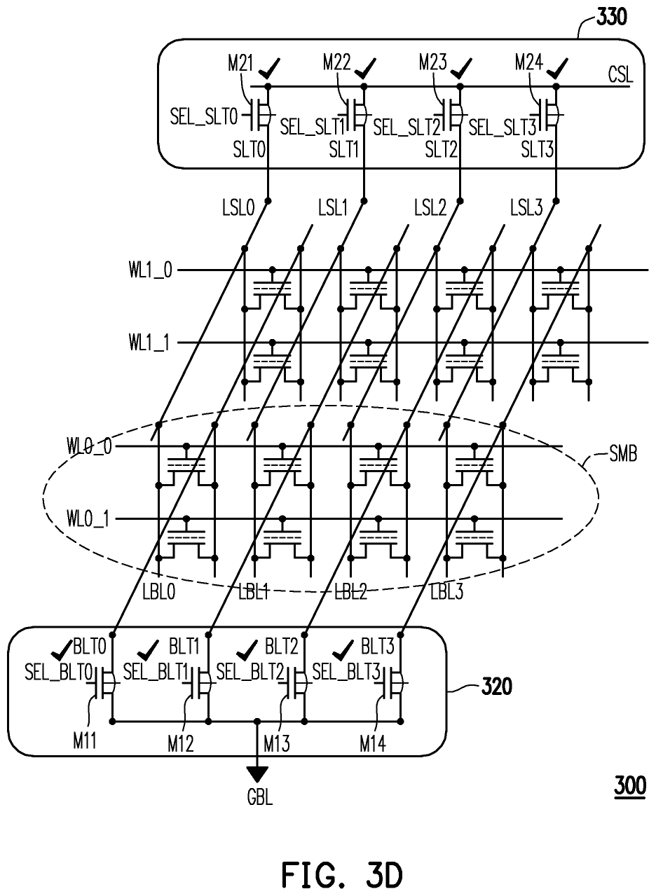

Referring to FIG. 3A to FIG. 3D, FIG. 3A to FIG. 3D are schematic views illustrating access operations of a three dimension memory device according to an embodiment of the disclosure. In FIG. 3A, in a three dimension memory device 300, the transistors M21 to M24 as the source line switches SLT0 to SLT3 and the transistors M11 to M14 as the bit line switches BLT0 to BLT3 are all N-type transistors with a triple-well substrate.

In the read operation, a substrate 320 (P-type well region) of the transistors M11 to M14 is applied with a bias voltage equal to 0 volts, and a substrate 330 (P-type well region) of the transistors M21 to M24 is also applied with a bias voltage equal to 0 volts. Corresponding to the selected memory cell SMC, the bit line LBL2 and the source line LSL2 are the selected bit line and the selected source line, respectively. The bit line switch BLT2 and the source line switch SLT2 are the selected bit line switch and the selected source line switch, respectively and are turned on. The remaining bit line switches BLT0, BLT1, and BLT3 and the remaining source line switches SLT0, SLT1, and SLT3 are cut-off. Meanwhile, the voltage on the common bit line GBL may be equal to the first voltage, and the turned-on bit line switch BLT2 may provide the first voltage to the bit line LBL2 of the selected memory cell SMC. Moreover, meanwhile, the voltage on the common source line CSL is equal to the second voltage, and the turned-on source line switch SLT2 may provide the second voltage to the source line LSL2 corresponding to the selected memory cell SMC. In the embodiment, the first voltage may be a positive value, and the first voltage is greater than the second voltage. For example, the first voltage may be 1 volt, and the second voltage may be 0 volts.

On the other hand, the electrical signal of the word line on the word line WL0_0 corresponding to the selected memory cell SMC may be equal to the read voltage (e.g., 5-7 volts). The electrical signals of the word lines on the word lines WL0_1, WL1_0, and WL1_1 that do not correspond to the selected memory cell SMC may be equal to 0 volts.

Moreover, the bit line switches BLT0, BLT1, and BLT3 and the source line switches SLT0, SLT1, and SLT3 are all cut-off, so the bit lines LBL0, LBL1, and LBL3 and the source lines LSL0, LSL1, and LSL3 are connected to the ground voltage in a floating state.

The selected memory cell SMC may transmit currents according to the stored data, which are transmitted to the sense amplifier (not shown) through the bit line LBL2. The sense amplifier may convert the currents provided by the selected memory cell SMC into a voltage signal and compare the voltage signal with a reference voltage to sense the data stored in the selected memory cell SMC.

In FIG. 3B, the three dimension memory device 300 performs program operations. Through the Fowler-Nordheim (FN) tunneling method, the threshold voltage of the selected memory cell SMC is adjusted, and program operations are performed.

In the program operation, the substrate 320 (P-type well region) of the transistors M11 to M14 and the substrate 330 (P-type well region) of the transistors M21 to M24 are both applied with a negative bias voltage (e.g., −7.5 volts). Moreover, the bit line switch BLT2 corresponding to the selected memory cell SMC is the selected bit line switch and is turned on. The remaining bit line switches BLT0, BLT1, and BLT3 are cut-off. The bit line switch BLT2 provides a negative first voltage to the bit line LBL2 corresponding to the selected memory cell SMC. The first voltage is −7.5 volts, for example. Moreover, the source line switch SLT2 corresponding to the selected memory cell SMC is set as the selected source line switch and is cut-off. The remaining source line switches SLT0, SLT1, and SLT3 are turned on. Meanwhile, the voltage on the common source line CSL is equal to 6.5 volts, for example. Based on the body effect, the turned-on source line switches SLT0, SLT1, and SLT3 may provide a positive second voltage (e.g., equal to 3.5 volts) to the source lines LSL0, LSL1, and LSL3 corresponding to the unselected memory cells. The second voltage is used as an inhibiting voltage. Meanwhile, the source line LSL2 is in a floating state.

Moreover, the word line voltage on the word line WL0_0 corresponding to the selected memory cell SMC may be set to 12.5 volts, and the word line voltages on the remaining word lines WL1_0, WL1_1, and WL0_1 may be set to −1.5 volts. In this way, the selected memory cell SMC may withstand a programmed bias voltage of up to 20 volts (the voltage difference between the word line and the bit line (or source line) corresponding to the memory cell during the program operation), and program operations may be effectively performed.

Regarding other unselected memory cells, the memory cells corresponding to the unselected bit lines, unselected source lines, and unselected word lines may have a programmed bias voltage of −5 volts; the memory cells corresponding to unselected bit lines, unselected source lines, and selected word lines may have a programmed bias voltage of 9 volts; the memory cells corresponding to the selected bit line, the selected source line, and the unselected word line may have a programmed bias voltage of 6 volts. The unselected memory cells may be effectively masked without being disturbed by program operations.

In FIG. 3C, the three dimension memory device 300 performs a byte erase operation. The selected memory cell SMC is selected to perform the erase operation based on the FN tunning method.

During the byte erase operation, the substrate 320 (P-type well region) of the transistors M11 to M14 and the substrate 330 (P-type well region) of the transistors M21 to M24 are both applied with negative bias voltages (e.g., −3.5 Volts). Moreover, the bit line switch BLT2 corresponding to the selected memory cell SMC is the selected bit line switch and is turned on. The remaining bit line switches BLT0, BLT1, and BLT3 are cut-off. The bit line switch BLT2 provides a positive first voltage to the bit line LBL2 corresponding to the selected memory cell SMC according to the voltage on the common bit line GBL. The voltage on the common bit line GBL is equal to 10.5 volts, for example. Based on the body effect, the bit line switch BLT2 may provide a first voltage equal to 7.5 volts to the bit line LBL2, for example.

Moreover, the source line switch SLT2 corresponding to the selected memory cell SMC is set as the selected source line switch and is cut-off. The remaining source line switches SLT0, SLT1, and SLT3 are turned on. Meanwhile, the voltage on the common source line CSL is equal to −3.5 volts, for example. The turned-on source line switches SLT0, SLT1, and SLT3 may respectively provide a negative second voltage (e.g., equal to −3.5 volts) to the source lines LSL0, LSL1, and LSL3. Meanwhile, the source line LSL2 is in a floating state.

Moreover, the word line voltage on the word line WL0_0 corresponding to the selected memory cell SMC may be set to −12.5 volts, and the word line voltages on the remaining word lines WL1_0, WL1_1, and WL0_1 may be set to 1.5 volts. In this way, the selected memory cell SMC may withstand an erasing bias voltage of up to −20 volts (the voltage difference between the word line and the bit line (or source line) corresponding to the memory cell during the erase operation), and the erase operation is effectively performed.

Regarding other unselected memory cells, the memory cells corresponding to unselected bit lines, unselected source lines, and unselected word lines may have an erasing bias voltage of 5 volts; the memory cells corresponding to unselected bit lines, unselected source lines, and selected word lines may have an erasing bias voltage of −9 volts; the memory cells corresponding to the selected bit line, the selected source line, and the unselected word line may have an erasing bias voltage of −6 volts. The unselected memory cells may be effectively masked without being disturbed by the erase operation.

In FIG. 3D, the three dimension memory device 300 performs a sector erase operation. Multiple memory cells in a selected memory cell sector SMB are all selected to perform the erase operation.

In the sector erase operation, the substrate 320 (P-type well region) of the transistors M11 to M14 and the substrate 330 (P-type well region) of the transistors M21 to M24 are both applied with a bias voltage of 0 volts. The voltages on the common bit line GBL and the common source line CSL may be about 13 volts.

Moreover, the source line switches SLT0 to SLT3 and the bit line switches BLT0 to BLT3 are all turned on. Based on the body effect, the voltages on the source lines LSL0 to LSL3 and the bit lines LBL0 to LBL3 are all positive 10 volts.

Moreover, the word line voltages on the word lines WL0_0 and WL0_1 of the selected memory cell sector SMB may be set to −10 volts, and the word line voltages on the remaining word lines WL1_0 and WL1_1 may be set to 4 volts. In this way, the memory cells in the selected memory cell sector SMB may withstand an erasing bias voltage of up to −20 volts, and the erase operation may be effectively performed. The remaining memory cells that have not been erased may withstand an erasing bias voltage of −6 volts and may be masked without being disturbed by the erase operation.

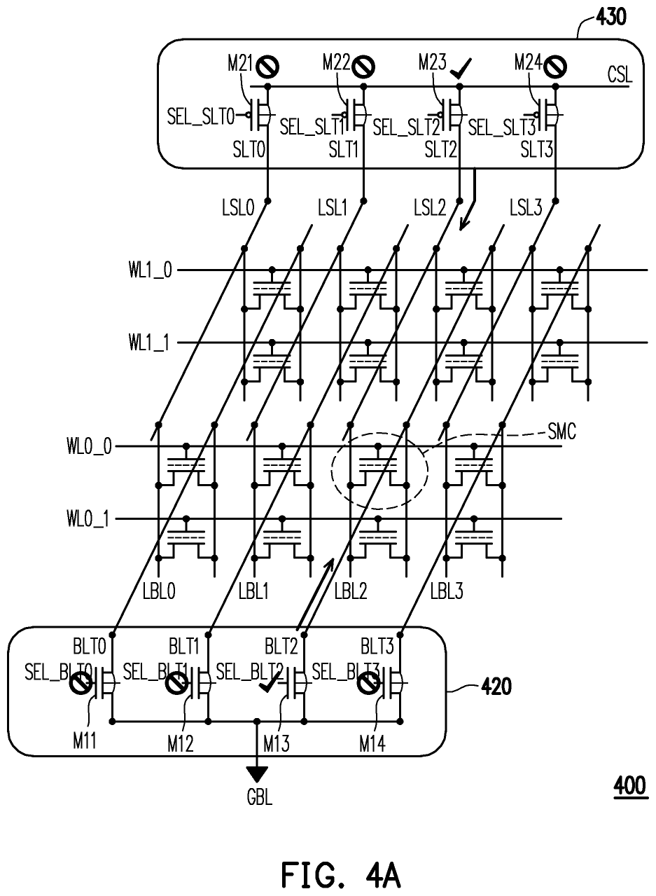

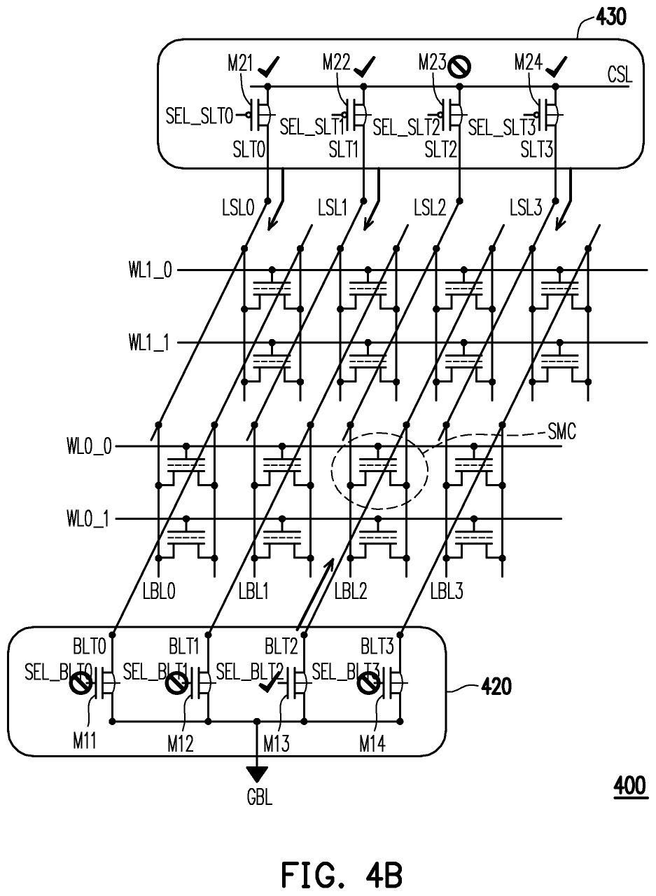

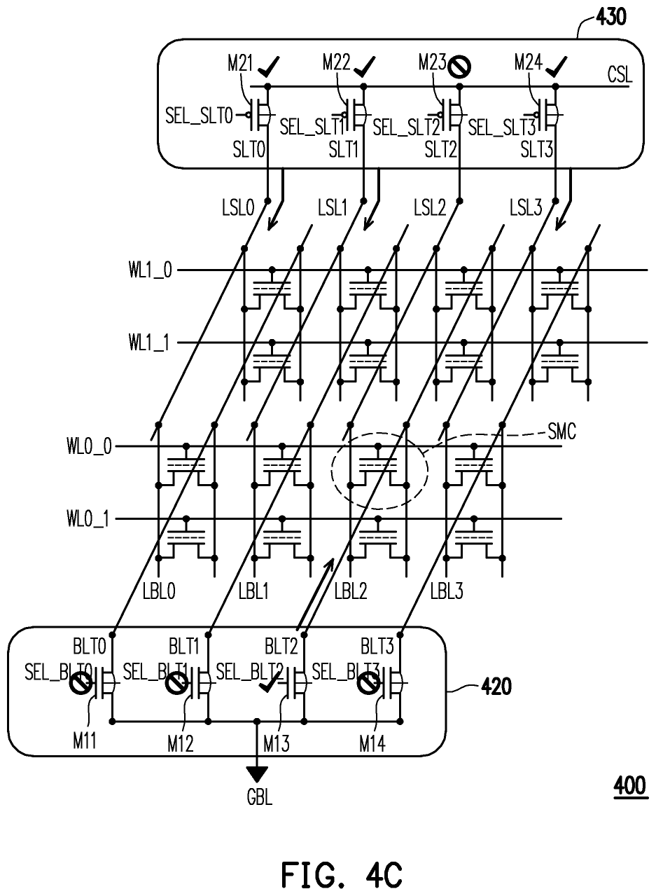

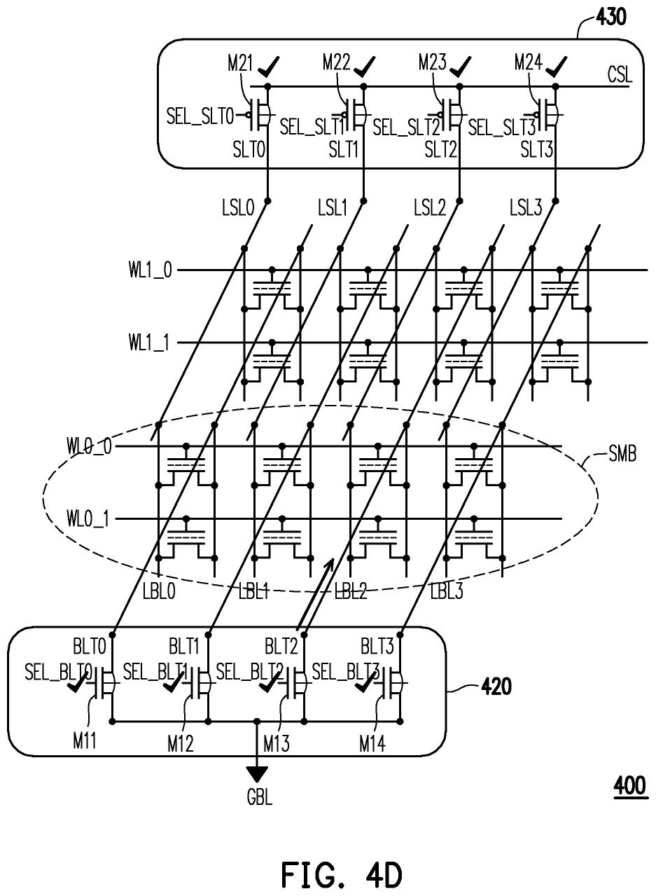

Referring to FIG. 4A to FIG. 4D, FIG. 4A to FIG. 4D are schematic views illustrating access operations of a three dimension memory device according to another embodiment of the disclosure. In FIG. 4A, in a three dimension memory device 400, the transistors M21 to M24 as the source line switches SLT0 to SLT3 are P-type transistors, and the transistors M11 to M14 as the bit line switches BLT0 to BLT3 are N-type transistors with a triple-well substrate.

In the read operation, a substrate 420 (P-type well region) of the transistors M11 to M14 is applied with a bias voltage equal to 0 volts, and a substrate 430 (N-type well region) of the transistors M21 to M24 is also applied with a bias voltage equal to 1.8 volts. Corresponding to the selected memory cell SMC, the bit line LBL2 and the source line LSL2 are the selected bit line and the selected source line, respectively. The bit line switch BLT2 and the source line switch SLT2 are the selected bit line switch and the selected source line switch, respectively and are turned on. The remaining bit line switches BLT0, BLT1, and BLT3 and the remaining source line switches SLT0, SLT1, and SLT3 are cut-off. Meanwhile, the voltage on the common bit line GBL may be equal to the first voltage, and the turned-on bit line switch BLT2 may provide the first voltage to the bit line LBL2 of the selected memory cell SMC. Moreover, meanwhile, the voltage on the common source line CSL is equal to the second voltage, and the turned-on source line switch SLT2 may provide the second voltage to the source line LSL2 corresponding to the selected memory cell SMC. In the embodiment, the first voltage may be a positive value, and the first voltage is greater than the second voltage. For example, the first voltage may be 1 volt, and the second voltage may be 0 volts.

On the other hand, the electrical signal of the word line on the word line WL0_0 corresponding to the selected memory cell SMC may be equal to the read voltage (e.g., 5-7 volts). The electrical signals of the word lines on the word lines WL0_1, WL1_0, and WL1_1 that do not correspond to the selected memory cell SMC may be equal to 0 volts.

Moreover, the bit line switches BLT0, BLT1, and BLT3 and the source line switches SLT0, SLT1, and SLT3 are all cut-off, so the bit lines LBL0, LBL1, and LBL3 and the source lines LSL0, LSL1, and LSL3 are connected to the ground voltage in a floating state.

The selected memory cell SMC may transmit currents according to the stored data, which are transmitted to the sense amplifier (not shown) through the bit line LBL2. The sense amplifier may convert the currents provided by the selected memory cell SMC into a voltage signal and compare the voltage signal with a reference voltage to sense the data stored in the selected memory cell SMC.

In FIG. 4B, the three dimension memory device 400 performs program operations. Through the Fowler-Nordheim (FN) tunning method, the threshold voltage of the selected memory cell SMC is adjusted, and program operations are performed.

In the program operation, a substrate 420 (P-type well region) of the transistors M11 to M14 is applied with a negative bias voltage (e.g., −10.5 volts), and a substrate 430 (N-type well region) of the transistors M21 to M24 is applied with a positive bias voltage (e.g., 3.5 volts). Moreover, the bit line switch BLT2 corresponding to the selected memory cell SMC is the selected bit line switch and is turned on. The remaining bit line switches BLT0, BLT1, and BLT3 are cut-off. The bit line switch BLT2 provides a negative first voltage to the bit line LBL2 corresponding to the selected memory cell SMC. The first voltage is −10.5 volts, for example. Moreover, the source line switch SLT2 corresponding to the selected memory cell SMC is set as the selected source line switch and is cut-off. The remaining source line switches SLT0, SLT1, and SLT3 are turned on. The turned-on source line switches SLT0, SLT1, and SLT3 may provide a positive second voltage approximately equal to 3.5 volts to the source lines LSL0, LSL1, and LSL3. The second voltage is used as an inhibiting voltage. Meanwhile, the source line LSL2 is in a floating state.

Moreover, the word line voltage on the word line WL0_0 corresponding to the selected memory cell SMC may be set to 12.5 volts, and the word line voltages on the remaining word lines WL1_0, WL1_1, and WL0_1 may be set to −1.5 volts. In this way, the selected memory cell SMC may withstand a programmed bias voltage of up to 23 volts (the voltage difference between the word line and the bit line (or source line) corresponding to the memory cell during the program operation), and program operations may be effectively performed.

Regarding other unselected memory cells, the memory cells corresponding to the unselected bit lines, unselected source lines, and unselected word lines may have a programmed bias voltage of −5 volts; the memory cells corresponding to unselected bit lines, unselected source lines, and selected word lines may have a programmed bias voltage of 9 volts; the memory cells corresponding to the selected bit line, the selected source line, and the unselected word line may have a programmed bias voltage of 9 volts. The unselected memory cells may be effectively masked without being disturbed by program operations.

In FIG. 4C, the three dimension memory device 400 performs a byte erase operation. The selected memory cell SMC is selected to perform the erase operation based on the FN tunneling method.

During the byte erase operation, the substrate 420 (P-type well region) of the transistors M11 to M14 is applied with a negative bias voltage (e.g., −6.5 volts), and the substrate 430 (P-type well region) of the transistors M21 to M24 is applied with a positive bias voltage (e.g., 7.5 volts). Moreover, the bit line switch BLT2 corresponding to the selected memory cell SMC is the selected bit line switch and is cut-off. The remaining bit line switches BLT0, BLT1, and BLT3 are turned on. The bit line switches BLT0, BLT1, and BLT3 provide a positive first voltage to multiple bit lines LBL0, LBL1, and LBL3 corresponding to the unselected memory cell SMC according to the voltage on the common bit line GBL. The voltage on the common bit line GBL is equal to −6.5 volts, for example. The bit line switches BLT0, BLT1, and BLT3 may provide a negative first voltage equal to −6.5 volts to the bit lines LBL0, LBL1, and LBL3, for example. The bit line LBL2 is in a floating state.

Moreover, the source line switch SLT2 corresponding to the selected memory cell SMC is set as the selected source line switch and is turned on. The remaining source line switches SLT0, SLT1, and SLT3 are cut-off. Meanwhile, the voltage on the common source line CSL is equal to 7.5 volts, for example. The turned-on source line switch SLT2 may provide a positive second voltage (e.g., equal to 7.5 volts) to the source line LSL2. Meanwhile, the source lines LSL0, LSL1, and LSL3 are in a floating state.

Moreover, the word line voltage on the word line WL0_0 corresponding to the selected memory cell SMC may be set to −12.5 volts, and the word line voltages on the remaining word lines WL1_0, WL1_1, and WL0_1 may be set to 1.5 volts. In this way, the selected memory cell SMC may withstand an erasing bias voltage of up to −20 volts (the voltage difference between the word line and the bit line (or source line) corresponding to the memory cell during the erase operation), and the erase operation is effectively performed.

Regarding other unselected memory cells, the memory cells corresponding to unselected bit lines, unselected source lines, and unselected word lines may have an erasing bias voltage of 8 volts; the memory cells corresponding to unselected bit lines, unselected source lines, and selected word lines may have an erasing bias voltage of −6 volts; the memory cells corresponding to the selected bit line, the selected source line, and the unselected word line may have an erasing bias voltage of −6 volts. The unselected memory cells may be effectively masked without being disturbed by the erase operation.

In FIG. 4D, the three dimension memory device 400 performs a sector erase operation. Multiple memory cells in the selected memory cell sector SMB are all selected to perform the erase operation.

In the sector erase operation, the substrate 420 (P-type well region) of the transistors M11 to M14 may be with applied a bias voltage of 0 volts. The substrate 430 (N-type well region) of the transistors M21 to M24 may be applied with a bias voltage of 10 volts. The voltage on the common bit line GBL may be about 13 volts, and the voltage on the common source line CSL may be about 10 volts.

Moreover, the source line switches SLT0 to SLT3 and the bit line switches BLT0 to BLT3 are all turned on. The voltages on the source lines LSL0 to LSL3 are all positive 10 volts. Moreover, based on the body effect, the voltages on the bit lines LBL0 to LBL3 are all positive 10 volts.

Moreover, the word line voltages on the word lines WL0_0 and WL0_1 of the selected memory cell sector SMB may be set to −10 volts, and the word line voltages on the remaining word lines WL1_0 and WL1_1 may be set to 4 volts. In this way, the memory cells in the selected memory cell sector SMB may withstand an erasing bias voltage of up to −20 volts, and the erase operation may be effectively performed. The remaining memory cells that have not been erased may withstand an erasing bias voltage of −6 volts and may be masked without being disturbed by the erase operation.

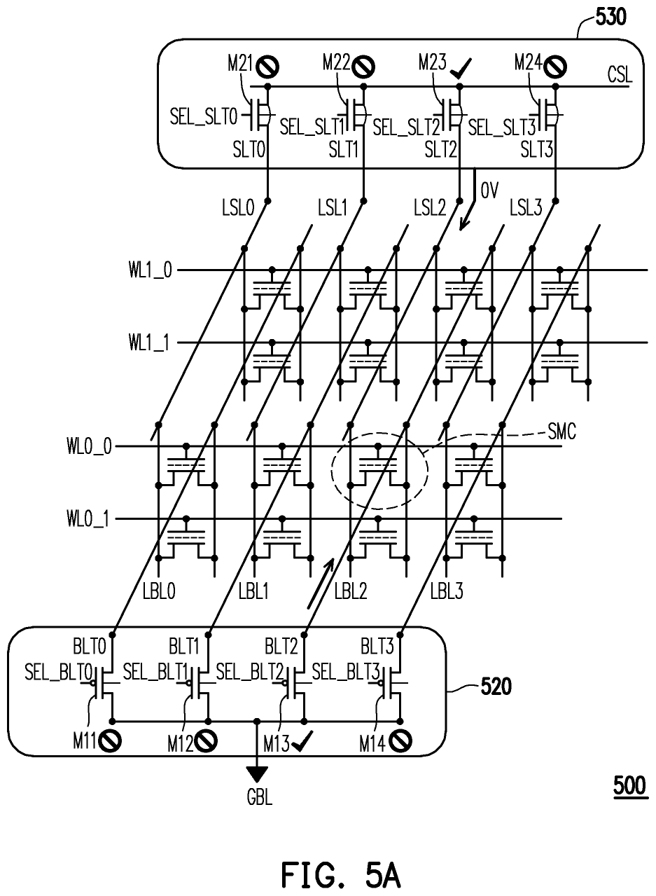

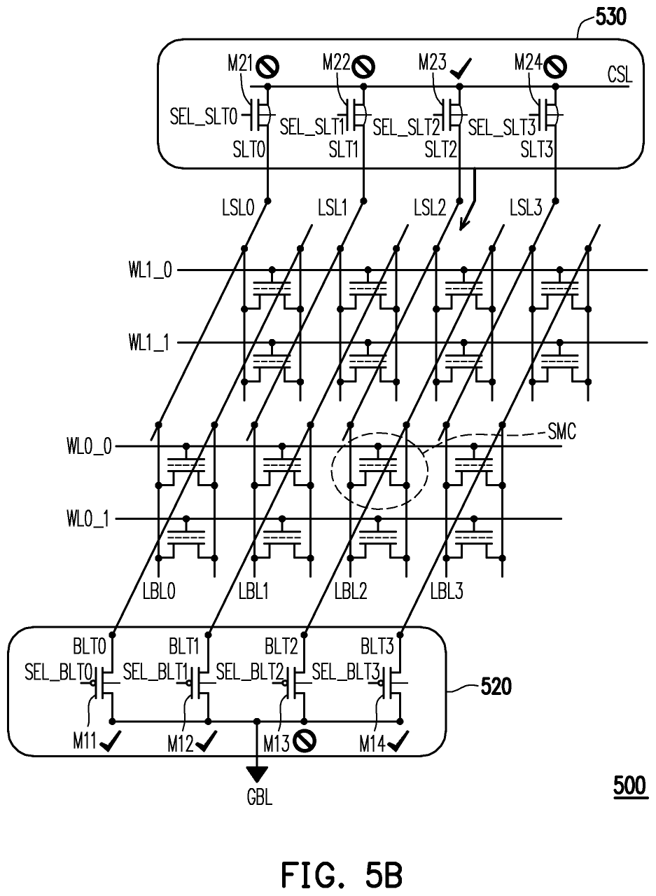

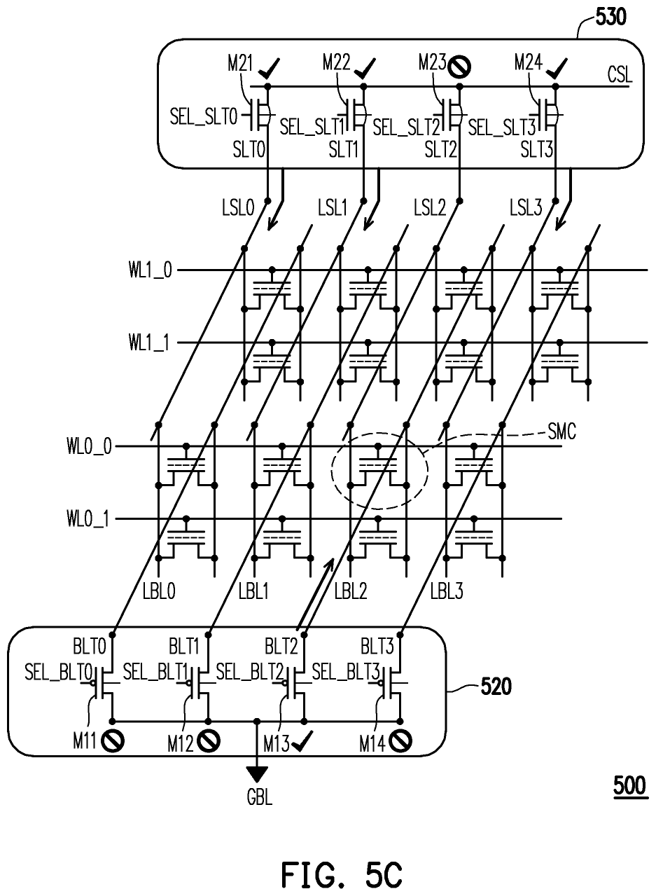

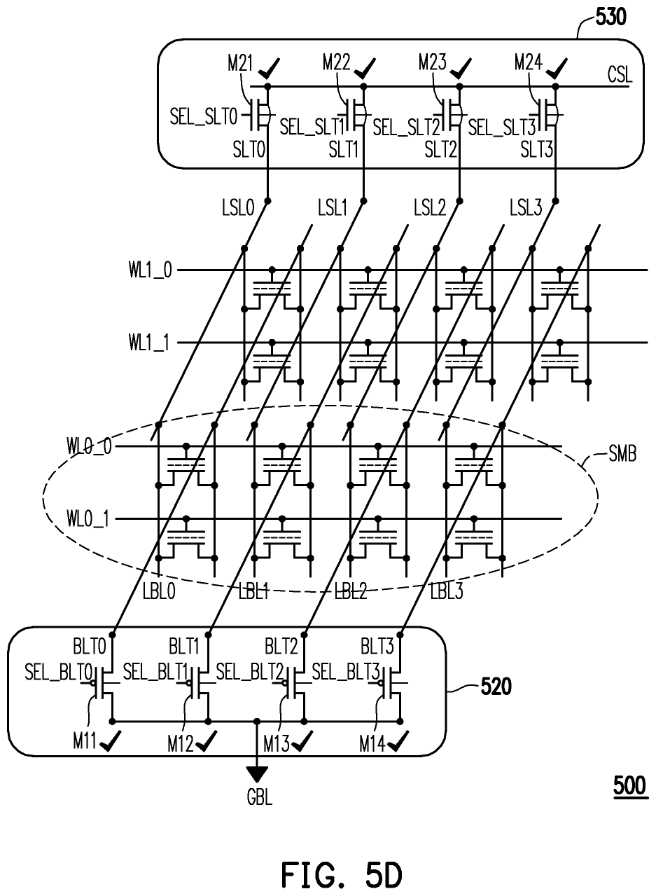

Referring to FIG. 5A to FIG. 5D, FIG. 5A to FIG. 5D are schematic views of access operations of a three dimension memory device according to another embodiment of the disclosure. In FIG. 5A, in a three dimension memory device 500, the transistors M21 to M24 as the source line switches SLT0 to SLT3 are N-type transistors with a triple-well substrate, and the transistors M11 to M14 as the bit line switches BLT0 to BLT3 are P-type transistors.

In the read operation, a substrate 420 (N-type well region) of the transistors M11 to M14 is applied with a bias voltage equal to 1.8 volts, and a substrate 430 (P-type well region) of the transistors M21 to M24 is also applied with a bias voltage equal to 0 volts. Corresponding to the selected memory cell SMC, the bit line LBL2 and the source line LSL2 are the selected bit line and the selected source line, respectively. The bit line switch BLT2 and the source line switch SLT2 are the selected bit line switch and the selected source line switch, respectively and are turned on. The remaining bit line switches BLT0, BLT1, and BLT3 and the remaining source line switches SLT0, SLT1, and SLT3 are cut-off. Meanwhile, the voltage on the common bit line GBL may be equal to the first voltage, and the turned-on bit line switch BLT2 may provide the first voltage to the bit line LBL2 of the selected memory cell SMC. Moreover, meanwhile, the voltage on the common source line CSL is equal to the second voltage, and the turned-on source line switch SLT2 may provide the second voltage to the source line LSL2 corresponding to the selected memory cell SMC. In the embodiment, the first voltage may be a positive value, and the first voltage is greater than the second voltage. For example, the first voltage may be 1 volt, and the second voltage may be 0 volts.

On the other hand, the electrical signal of the word line on the word line WL0_0 corresponding to the selected memory cell SMC may be equal to the read voltage (e.g., 5-7 volts). The electrical signals of the word lines on the word lines WL0_1, WL1_0, and WL1_1 that do not correspond to the selected memory cell SMC may be equal to 0 volts.

Moreover, the bit line switches BLT0, BLT1, and BLT3 and the source line switches SLT0, SLT1, and SLT3 are all cut-off, so the bit lines LBL0, LBL1, and LBL3 and the source lines LSL0, LSL1, and LSL3 are connected to the ground voltage in a floating state.

The selected memory cell SMC may transmit currents according to the stored data, which are transmitted to the sense amplifier (not shown) through the bit line LBL2. The sense amplifier may convert the currents provided by the selected memory cell SMC into a voltage signal and compare the voltage signal with a reference voltage to sense the data stored in the selected memory cell SMC.

In FIG. 5B, the three dimension memory device 500 performs program operations. Through the Fowler-Nordheim (FN) tunneling method, the threshold voltage of the selected memory cell SMC is adjusted, and program operations are performed.

In the program operation, a substrate 420 (N-type well region) of the transistors M11 to M14 is applied with a positive bias voltage (e.g., 3.5 volts), and a substrate 430 (P-type well region) of the transistors M21 to M24 is applied with a negative bias voltage (e.g., −10.5 volts). Moreover, the bit line switch BLT2 corresponding to the selected memory cell SMC is the selected bit line switch and is cut-off. The remaining bit line switches BLT0, BLT1, and BLT3 are turned on. The bit line switches BLT0, BLT1, and BLT3 provide a positive first voltage to the bit lines LBL0, LBL1, and LBL3 corresponding to multiple unselected memory cell SMC. The first voltage is 3.5 volts, for example. Moreover, the source line switch SLT2 corresponding to the selected memory cell SMC is set as the selected source line switch and is turned on. The remaining source line switches SLT0, SLT1, and SLT3 are cut-off. The turned-on source line switch SLT2 may provide a negative second voltage (e.g., equal to −1.5 volts) to the source line LSL2. The first voltage is used as an inhibiting voltage. Meanwhile, the bit line LBL2 is in a floating state.

Moreover, the word line voltage on the word line WL0_0 corresponding to the selected memory cell SMC may be set to 12.5 volts, and the word line voltages on the remaining word lines WL1_0, WL1_1, and WL0_1 may be set to −1.5 volts. In this way, the selected memory cell SMC may withstand a programmed bias voltage of up to 23 volts (the voltage difference between the word line and the bit line (or source line) corresponding to the memory cell during the program operation), and program operations may be effectively performed.

Regarding other unselected memory cells, the memory cells corresponding to the unselected bit lines, unselected source lines, and unselected word lines may have a programmed bias voltage of −5 volts; the memory cells corresponding to unselected bit lines, unselected source lines, and selected word lines may have a programmed bias voltage of 9 volts; the memory cells corresponding to the selected bit line, the selected source line, and the unselected word line may have a programmed bias voltage of 9 volts. The unselected memory cells may be effectively masked without being disturbed by program operations.

In FIG. 5C, the three dimension memory device 500 performs a byte erase operation. The selected memory cell SMC is selected to perform the erase operation based on the FN tunneling method.

During the byte erase operation, the substrate 420 (N-type well region) of the transistors M11 to M14 is applied with a positive bias voltage (e.g., 7.5 volts), and the substrate 430 (P-type well region) of the transistors M21 to M24 is applied with a negative bias voltage (e.g., −4.5 volts). Moreover, the bit line switch BLT2 corresponding to the selected memory cell SMC is the selected bit line switch and is turned on. The remaining bit line switches BLT0, BLT1, and BLT3 are cut-off. The bit line switch BLT2 provide a positive first voltage to the bit line LBL2 corresponding to the selected memory cell SMC according to the voltage on the common bit line GBL. The voltage on the common bit line GBL is equal to 7.5 volts, for example. The bit line switch BLT2 may provide a positive first voltage (e.g., equal to 7.5 volts) to the bit line LBL2, for example. The bit lines LBL0, LBL1, and LBL3 are in a floating state.

Moreover, the source line switch SLT2 corresponding to the selected memory cell SMC is set as the selected source line switch and is cut-off. The remaining source line switches SLT0, SLT1, and SLT3 are turned on. Meanwhile, the voltage on the common source line CSL is equal to −4.5 volts, for example. The turned-on source line switches SLT0, SLT1, and SLT3 may provide a negative second voltage (e.g., equal to −4.5 volts) to the source lines LSL0, LSL1, and LSL3 corresponding to the unselected memory cells. Meanwhile, the source line LSL2 is in a floating state.

Moreover, the word line voltage on the word line WL0_0 corresponding to the selected memory cell SMC may be set to −12.5 volts, and the word line voltages on the remaining word lines WL1_0, WL1_1, and WL0_1 may be set to 1.5 volts. In this way, the selected memory cell SMC may withstand an erasing bias voltage of up to −20 volts (the voltage difference between the word line and the bit line (or source line) corresponding to the memory cell during the erase operation), and the erase operation is effectively performed.

Regarding other unselected memory cells, the memory cells corresponding to unselected bit lines, unselected source lines, and unselected word lines may have an erasing bias voltage of 6 volts; the memory cells corresponding to unselected bit lines, unselected source lines, and selected word lines may have an erasing bias voltage of −8 volts; the memory cells corresponding to the selected bit line, the selected source line, and the unselected word line may have an erasing bias voltage of −6 volts. The unselected memory cells may be effectively masked without being disturbed by the erase operation.

In FIG. 5D, the three dimension memory device 500 performs a sector erase operation. Multiple memory cells in the selected memory cell sector SMB are all selected to perform the erase operation.

In the sector erase operation, the substrate 420 (N-type well region) of the transistors M11 to M14 may be with applied a bias voltage of 10 volts. The substrate 430 (P-type well region) of the transistors M21 to M24 may be applied with a bias voltage of 0 volts. The voltage on the common bit line GBL may be about 10 volts, and the voltage on the common source line CSL may be about 13 volts.

Moreover, the source line switches SLT0 to SLT3 and the bit line switches BLT0 to BLT3 are all turned on. The voltages on the source lines LSL0 to LSL3 are all positive 10 volts. Moreover, based on the body effect, the voltages on the bit lines LBL0 to LBL3 are all positive 10 volts.

Moreover, the word line voltages on the word lines WL0_0 and WL0_1 of the selected memory cell sector SMB may be set to −10 volts, and the word line voltages on the remaining word lines WL1_0 and WL1_1 may be set to 4 volts. In this way, the memory cells in the selected memory cell sector SMB may withstand an erasing bias voltage of up to −20 volts, and the erase operation may be effectively performed. The remaining memory cells that have not been erased may withstand an erasing bias voltage of −6 volts and may be masked without being disturbed by the erase operation.

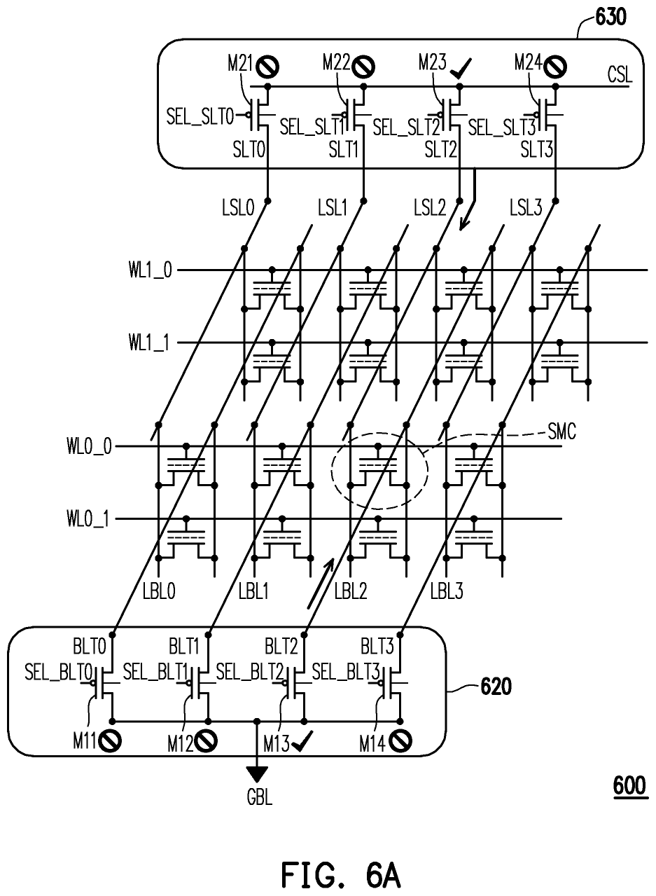

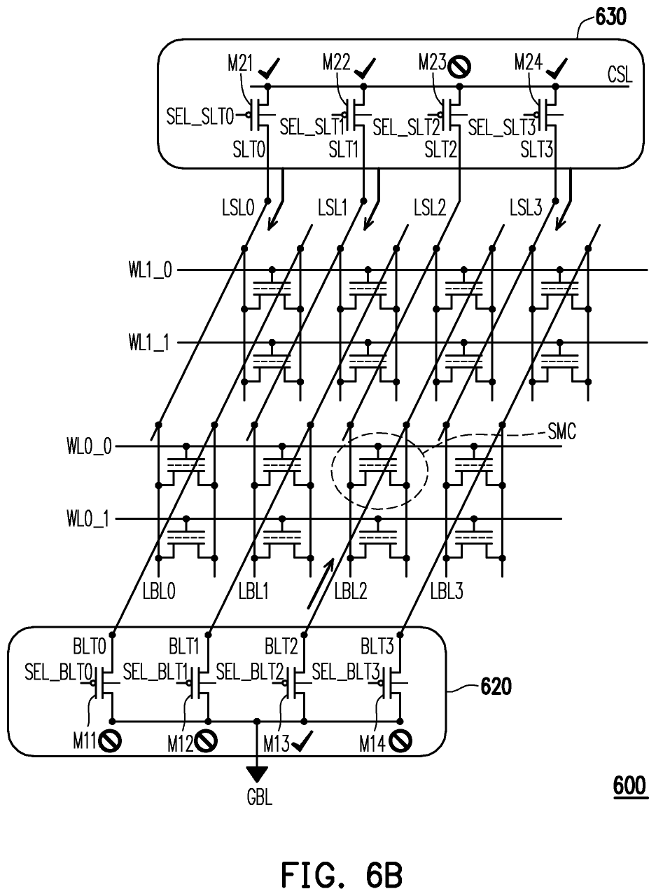

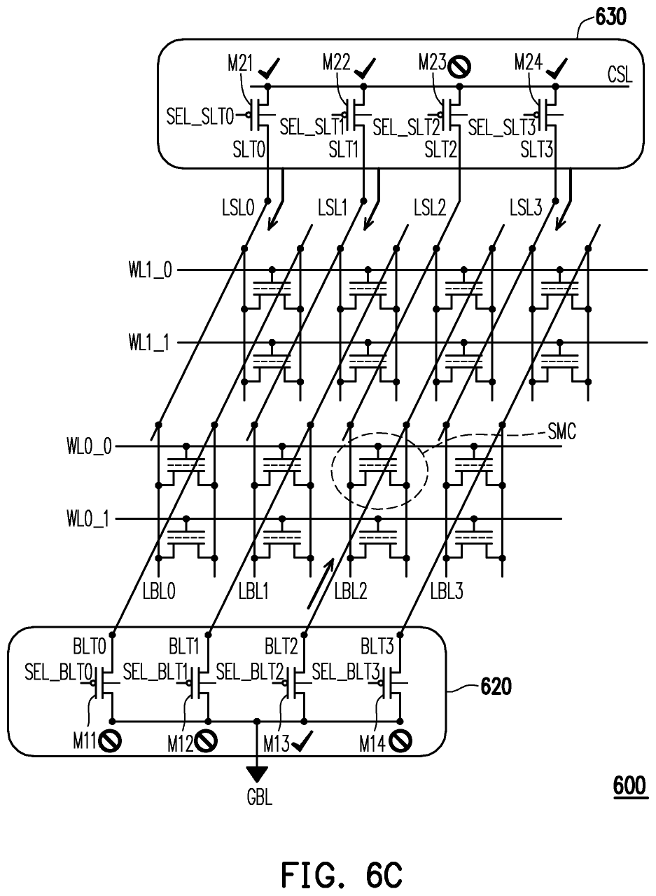

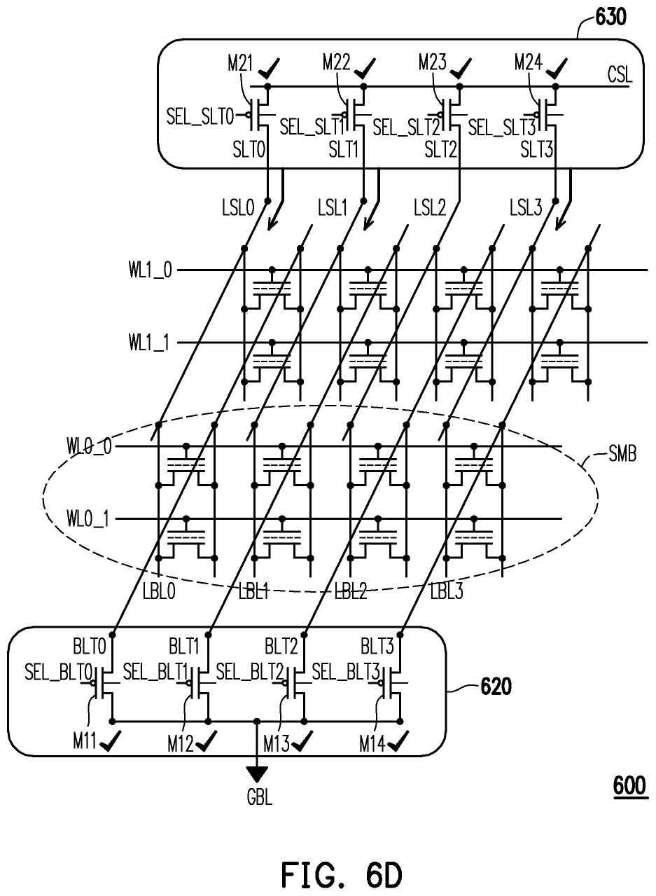

Referring to FIG. 6A to FIG. 6D, FIG. 6A to FIG. 6D are schematic views of access operations of a three dimension memory device according to another embodiment of the disclosure. In FIG. 6A, in a three dimension memory device 600, the transistors M21 to M24 as the source line switches SLT0 to SLT3 and the transistors M11 to M14 as the bit line switches BLT0 to BLT3 are all P-type transistors.

In the read operation, a substrate 420 (N-type well region) of the transistors M11 to M14 is applied with a bias voltage equal to 1.8 volts, and a substrate 430 (N-type well region) of the transistors M21 to M24 is also applied with a bias voltage equal to 1.8 volts. Corresponding to the selected memory cell SMC, the bit line LBL2 and the source line LSL2 are the selected bit line and the selected source line, respectively. The bit line switch BLT2 and the source line switch SLT2 are the selected bit line switch and the selected source line switch, respectively and are turned on. The remaining bit line switches BLT0, BLT1, and BLT3 and the remaining source line switches SLT0, SLT1, and SLT3 are cut-off. Meanwhile, the voltage on the common bit line GBL may be equal to the first voltage, and the turned-on bit line switch BLT2 may provide the first voltage to the bit line LBL2 of the selected memory cell SMC. Moreover, meanwhile, the voltage on the common source line CSL is equal to the second voltage, and the turned-on source line switch SLT2 may provide the second voltage to the source line LSL2 corresponding to the selected memory cell SMC. In the embodiment, the first voltage may be a positive value, and the first voltage is greater than the second voltage. For example, the first voltage may be 1 volt, and the second voltage may be 0 volts.

On the other hand, the electrical signal of the word line on the word line WL0_0 corresponding to the selected memory cell SMC may be equal to the read voltage (e.g., 5-7 volts). The electrical signals of the word lines on the word lines WL0_1, WL1_0, and WL1_1 that do not correspond to the selected memory cell SMC may be equal to 0 volts.

Moreover, the bit line switches BLT0, BLT1, and BLT3 and the source line switches SLT0, SLT1, and SLT3 are all cut-off, so the bit lines LBL0, LBL1, and LBL3 and the source lines LSL0, LSL1, and LSL3 are connected to the ground voltage in a floating state.

The selected memory cell SMC may transmit currents according to the stored data, which are transmitted to the sense amplifier (not shown) through the bit line LBL2. The sense amplifier may convert the currents provided by the selected memory cell SMC into a voltage signal and compare the voltage signal with a reference voltage to sense the data stored in the selected memory cell SMC.

In FIG. 6B, the three dimension memory device 600 performs program operations. Through the Fowler-Nordheim (FN) tunning method, the threshold voltage of the selected memory cell SMC is adjusted, and program operations are performed.

In the program operation, the substrate of the transistors M11 to M14 and the substrate 420 (N-type well region) of the transistors M21 to M24 are both applied with a positive bias voltage (e.g., 3.5 volts). Moreover, the bit line switch BLT2 corresponding to the selected memory cell SMC is the selected bit line switch and is turned on. The remaining bit line switches BLT0, BLT1, and BLT3 are cut-off. The bit line switch BLT2 provides a positive first voltage to the bit line LBL2 corresponding to the selected memory cell SMC. The first voltage is −7.5 volts, for example. Moreover, the source line switch SLT2 corresponding to the selected memory cell SMC is set as the selected source line switch and is cut-off. The remaining source line switches SLT0, SLT1, and SLT3 are turned on. Meanwhile, the voltage on the common source line CSL is equal to 6.5 volts, for example. The turned-on source line switches SLT0, SLT1, and SLT3 may provide a positive second voltage (e.g., equal to 3.5 volts) to the source lines LSL0, LSL1, and LSL3. The second voltage is used as an inhibiting voltage. Meanwhile, the source line LSL2 is in a floating state.

Moreover, the word line voltage on the word line WL0_0 corresponding to the selected memory cell SMC may be set to 12.5 volts, and the word line voltages on the remaining word lines WL1_0, WL1_1, and WL0_1 may be set to −1.5 volts. In this way, the selected memory cell SMC may withstand a programmed bias voltage of up to 20 volts (the voltage difference between the word line and the bit line (or source line) corresponding to the memory cell during the program operation), and program operations may be effectively performed.

Regarding other unselected memory cells, the memory cells corresponding to the unselected bit lines, unselected source lines, and unselected word lines may have a programmed bias voltage of −5 volts; the memory cells corresponding to unselected bit lines, unselected source lines, and selected word lines may have a programmed bias voltage of 9 volts; the memory cells corresponding to the selected bit line, the selected source line, and the unselected word line may have a programmed bias voltage of 6 volts. The unselected memory cells may be effectively masked without being disturbed by program operations.

In FIG. 6C, the three dimension memory device 600 performs a byte erase operation. The selected memory cell SMC is selected to perform the erase operation based on the FN tunneling method.

During the byte erase operation, the substrates 420 and 430 (N-type well region) of the transistors M11 to M14 and the the transistors M21 to M24 are both applied with a positive bias voltage (e.g., 7.5 volts). Moreover, the bit line switch BLT2 corresponding to the selected memory cell SMC is the selected bit line switch and is turned on. The remaining bit line switches BLT0, BLT1, and BLT3 are cut-off. The bit line switch BLT2 provide a positive first voltage to the bit line LBL2 corresponding to the selected memory cell SMC according to the voltage on the common bit line GBL. The voltage on the common bit line GBL is equal to 7.5 volts, for example. The bit line switch BLT2 may provide a positive first voltage (e.g., equal to 7.5 volts) to the bit line LBL2, for example. The bit lines LBL0, LBL1, and LBL3 are in a floating state.

Moreover, the source line switch SLT2 corresponding to the selected memory cell SMC is set as the selected source line switch and is cut-off. The remaining source line switches SLT0, SLT1, and SLT3 are turned on. Meanwhile, the voltage on the common source line CSL is equal to −6.5 volts, for example. Based on the body effect, the turned-on source line switches SLT0, SLT1, and SLT3 may provide a negative second voltage (e.g., equal to −3.5 volts) to the source lines LSL0, LSL1, and LSL3 corresponding to the unselected memory cells. Meanwhile, the source line LSL2 is in a floating state.

Moreover, the word line voltage on the word line WL0_0 corresponding to the selected memory cell SMC may be set to −12.5 volts, and the word line voltages on the remaining word lines WL1_0, WL1_1, and WL0_1 may be set to 1.5 volts. In this way, the selected memory cell SMC may withstand an erasing bias voltage of up to −20 volts (the voltage difference between the word line and the bit line (or source line) corresponding to the memory cell during the erase operation), and the erase operation is effectively performed.

Regarding other unselected memory cells, the memory cells corresponding to unselected bit lines, unselected source lines, and unselected word lines may have an erasing bias voltage of 5 volts; the memory cells corresponding to unselected bit lines, unselected source lines, and selected word lines may have an erasing bias voltage of −9 volts; the memory cells corresponding to the selected bit line, the selected source line, and the unselected word line may have an erasing bias voltage of −6 volts. The unselected memory cells may be effectively masked without being disturbed by the erase operation.

In FIG. 6D, the three dimension memory device 600 performs a sector erase operation. Multiple memory cells in the selected memory cell sector SMB are all selected to perform the erase operation.

In the sector erase operation, the substrates 420 and 430 (N-type well region) of the transistors M11 to M14 and the transistors M21 to M24 may be both applied with a bias voltage of 10 volts. The voltages on the common bit line GBL and on the common source line CSL may be both about 13 volts.

Moreover, the source line switches SLT0 to SLT3 and the bit line switches BLT0 to BLT3 are all turned on. The voltages on the source lines LSL0 to LSL3 are all positive 10 volts. The voltages on the bit lines LBL0 to LBL3 are also positive 10 volts.

Moreover, the word line voltages on the word lines WL0_0 and WL0_1 of the selected memory cell sector SMB may be set to −10 volts, and the word line voltages on the remaining word lines WL1_0 and WL1_1 may be set to 4 volts. In this way, the memory cells in the selected memory cell sector SMB may withstand an erasing bias voltage of up to −20 volts, and the erase operation may be effectively performed. The remaining memory cells that have not been erased may withstand an erasing bias voltage of −6 volts and may be masked without being disturbed by the erase operation.

Note that the multiple voltage values mentioned in the foregoing multiple embodiments are only proposed for the convenience of description and are not intended to limit the scope of implementation of the disclosure. Those with ordinary knowledge in the art may set various voltage values according to the process parameters of the integrated circuit and the voltage range of the operating power supply of the three dimension memory device, and there is no particular limitation.

In summary, in the three dimension memory device of the disclosure, the bit line switch and the word line switch may be configured by using a P-type transistor or an N-type transistor with a triple-well substrate. Moreover, by applying an appropriate substrate voltage, the bit line switch and the word line switch may pass positive or negative bit line voltages and source line voltages. In this way, when the access operation of the memory cell is performed, an appropriate voltage may be effectively applied to the selected and unselected memory cells to ensure that the access operation may be performed correctly.

1. A three dimension memory device, comprising:
a plurality of memory arrays, wherein the memory arrays comprise a plurality of corresponding memory cell rows, and the memory cell rows are respectively coupled to a plurality of source lines and a plurality of bit lines;
a plurality of bit line switches respectively configured with a plurality of first transistors, wherein first ends of the first transistors are coupled to a common bit line, and second ends of the first transistors are respectively coupled to the bit lines; and
a plurality of source line switches respectively configured with a plurality of second transistors, wherein first ends of the second transistors are coupled to a common source line, and second ends of the second transistors are respectively coupled to the source lines,
wherein the first transistors are P-type transistors or N-type transistors with a triple-well substrate, and the second transistors are P-type transistors or N-type transistors with a triple-well substrate.

2. The three dimension memory device according to claim 1, wherein the first transistors are controlled to be turned on or cut-off by a plurality of first selection signals, and the second transistors are controlled to be turned on or cut-off by a plurality of second selection signals.

3. The three dimension memory device according to claim 1, wherein on/off states of each bit line switch and each source line switch corresponding to a same memory cell row are the same.

4. The three dimension memory device according to claim 1, wherein the memory arrays are divided into a plurality of memory cell rows, and the memory cell rows receive a plurality of word line signals respectively.

5. The three dimension memory device according to claim 4, wherein in a read operation, a selected bit line switch corresponding to a selected memory cell is turned on and provides a first voltage to the selected memory cell, and a selected source line switch corresponding to the selected memory cell is turned on and provides a second voltage to the selected memory cell, wherein the first voltage is greater than the second voltage.

6. The three dimension memory device according to claim 4, wherein each of the first transistors and each of the second transistors are both N-type transistors with a triple-well substrate; in a program operation, a selected bit line switch corresponding to a selected memory cell is turned on and provides a negative first voltage to the selected memory cell, a selected source line switch corresponding to the selected memory cell is cut-off, a plurality of remaining unselected source line switches are turned on and provide a positive second voltage to a plurality of unselected memory cells, among the word line signals, a selected word line signal corresponding to the selected memory cell is a positive third voltage, and a plurality of remaining unselected word line signals are negative fourth voltages.

7. The three dimension memory device according to claim 4, wherein each of the first transistors and each of the second transistors are both N-type transistors with a triple-well substrate; in a byte erase operation, a selected bit line switch corresponding to a selected memory cell is turned on and provides a positive first voltage to the selected memory cell, a selected source line switch corresponding to a selected memory cell is cut-off, a plurality of unselected source line switches are turned on and provide a negative second voltage to a plurality of unselected memory cells, among the word line signals, a selected word line signal corresponding to the selected memory cell is a negative third voltage, and a plurality of unselected word line signals are a positive fourth voltage.

8. The three dimension memory device according to claim 4, wherein each of the first transistors and each of the second transistors are both N-type transistors with a triple-well substrate; in a sector erase operation, the bit line switches and the source line switches are all turned on and respectively provide a positive first voltage to the memory cells, a plurality of selected word line signals corresponding to a selected memory cell sector is a negative second voltage, and a plurality of selected word line signals corresponding to at least one unselected memory cell sector are a positive third voltage.

9. The three dimension memory device according to claim 4, wherein each of the first transistors is an N-type transistor with a triple-well substrate; each of the second transistors is a P-type transistor; and in a program operation, a selected bit line switch corresponding to a selected memory cell is turned on and provides a negative first voltage to the selected memory cell, a selected source line switch corresponding to the selected memory cell is cut-off, a plurality of unselected source line switches are turned on and provide a positive second voltage to a plurality of unselected memory cells, among the word line signals, a selected word line signal corresponding to the selected memory cell is a positive third voltage, a plurality of unselected word line signals are a negative fourth voltage.

10. The three dimension memory device according to claim 4, wherein each of the first transistors is an N-type transistor with a triple-well substrate; each of the second transistors is a P-type transistor; in the byte erase operation, a selected bit line switch corresponding to a selected memory cell is cut-off, a plurality of unselected bit line switches are turned on and provide a negative first voltage to a plurality of unselected memory cells, and a selected source line switch corresponding to the selected memory cell is turned on and provides a positive second voltage to the selected memory cell, among the word line signals, a selected word line signal corresponding to the selected memory cell is a negative third voltage, and a plurality of unselected word line signals are a positive fourth voltage.

11. The three dimension memory device according to claim 4, wherein each of the first transistors is an N-type transistor with a triple-well substrate; each of the second transistors is a P-type transistor; in a sector erase operation, the bit line switches and the source line switches are all turned on and respectively provide a positive first voltage to the memory cells, a plurality of selected word line signals corresponding to a selected memory cell sector are a negative second voltage, and a plurality of selected word line signals corresponding to at least one unselected memory cell sector are a positive third voltage.

12. The three dimension memory device according to claim 4, wherein each of the first transistors is a P-type transistor; each of the second transistors is an N-type transistor with a triple-well substrate; in a program operation, a selected bit line switch corresponding to a selected memory cell is turned on and provides a positive first voltage to the selected memory cell, a selected source line switch corresponding to the selected memory cell is turned on and provides a negative second voltage to the selected memory cell, among the word line signals, a selected word line signal corresponding to the selected memory cell is a positive third voltage, and a plurality of unselected word line signals are a negative fourth voltage.

13. The three dimension memory device according to claim 4, wherein each of the first transistors is a P-type transistor; each of the second transistors is an N-type transistor with a triple-well substrate; in a byte erase operation, a selected bit line switch corresponding to a selected memory cell is turned on and provides a positive first voltage to the selected memory cell, a selected source line switch corresponding to the selected memory cell is cut-off, a plurality of unselected source line switches are turned on and provide a negative second voltage to a plurality of unselected memory cells, among the word line signals, a selected word line signal corresponding to the selected memory cell is a negative fourth voltage, and a plurality of unselected word line signals are a positive fourth voltage.

14. The three dimension memory device according to claim 4, wherein each of the first transistors is a P-type transistor; each of the second transistors is an N-type transistor with a triple-well substrate; in a sector erase operation, the bit line switches and the source line switches are all turned on and respectively provide a positive first voltage to the memory cells, a plurality of selected word line signals corresponding to a selected memory cell sector is a negative second voltage, and a plurality of selected word line signals corresponding to at least one unselected memory cell sector are a positive third voltage.

15. The three dimension memory device according to claim 4, wherein the first transistors and the second transistors are both P-type transistors; in a program operation, a selected bit line switch corresponding to a selected memory cell is turned on and provides a negative first voltage to the selected memory cell, a selected source line switch corresponding to the selected memory cell is cut-off, a plurality of unselected source line switches are turned on and provide a positive second voltage to a plurality of unselected memory cells, among the word line signals, a selected word line signal corresponding to the selected memory cell is a positive third voltage, and a plurality of unselected word line signals are negative fourth voltages.

16. The three dimension memory device according to claim 4, wherein the first transistors and the second transistors are both P-type transistors; in a byte erase operation, a selected bit line switch corresponding to a selected memory cell is turned on and provides a positive first voltage to the selected memory cell, a selected source line switch corresponding to a selected memory cell is cut-off, a plurality of unselected source line switches are turned on and provide a negative second voltage to a plurality of unselected memory cells, among the word line signals, a selected word line signal corresponding to the selected memory cell is a negative third voltage, and a plurality of unselected word line signals are a positive fourth voltage.

17. The three dimension memory device according to claim 4, wherein the first transistors and the second transistors are both P-type transistors; in a sector erase operation, the bit line switches and the source line switches are all turned on and respectively provide a positive first voltage to the memory cells, a plurality of selected word line signals corresponding to a selected memory cell sector is a negative second voltage, and a plurality of selected word line signals corresponding to at least one unselected memory cell sector are a positive third voltage.

18. The three dimension memory device according to claim 1, wherein the memory arrays are AND flash memory arrays.

19. The three dimension memory device according to claim 1, wherein each of the source lines is coupled to the common source line only through each of the corresponding source line switches, and each of the bit lines is coupled to the common bit line only through each of the corresponding bit line switches.

20. The three dimension memory device according to claim 1, wherein each of the second transistors that is an N-type transistor with a triple-well substrate comprises:
an N-type deep well region;
a P-type well region formed on the N-type deep well region;
an N-type well region formed on sides of the P-type well region;
a first N-type heavily doped region, a second N-type heavily doped region, and a P-type heavily doped region formed on the P-type well region, wherein the first N-type heavily doped region and the second N-type heavily doped region forms a channel, and the P-type heavily doped region is used to receive a bias voltage; and
a gate structure formed on the first N-type heavily doped region, the second N-type heavily doped region, and the channel.
